(19) United States
(12) Patent Application Publication
(10) Pub. No.: US 2009/0086639 A1
(43) Pub. Date: Apr. 2, 2009

(54) TESTING DYNAMICALLY ADDRESSED NETWORK DEVICES

(75) Inventors: Roman KRZANOWSKI, White Plains, NY (US); Harry Soot-Shang Chu, Ardsley, NY (US)

Correspondence Address: VERIZON;PATENT MANAGEMENT GROUP, 1320 North Court House Road, 9th Floor, ARLINGTON, VA, 22201-2909, US

(73) Assignee: Verizon Services Corp., Arlington, VA (US)

(21) Appl. No.: 11/862,750

(22) Filed: Sep. 27, 2007

(51) Int. Cl. G01R 31/08; G06F 11/00; G06F 15/173

(52) U.S. Cl. 370/241; 370/251; 709/223

(57) ABSTRACT

A method may include receiving, at a first network device, a message from a second network device. The method may include determining whether the message is a test setup message, where the test setup message includes a network address associated with the second network device. A test sequence may be initiated with the second network device based on the network address when it is determined that the message is a test setup message.

### BACKGROUND INFORMATION

Durability and reliability in today's data networks is of utmost importance. Accordingly, active performance testing of such networks is routinely conducted in which two test end points exchange test data streams. Unfortunately, dynamic address provisioning of network devices significantly impairs a network operator's ability to easily and efficiently test such network devices.

### BRIEF DESCRIPTION OF THE DRAWINGS

FIG. 1 illustrates an exemplary network in which systems and methods described herein may be implemented;

FIG. 2 depicts an exemplary network device configured to communicate via the exemplary network illustrated in FIG. 1;

FIG. 3 is a flow diagram illustrating exemplary processing associated with establishing a testing environment between a statically addressed network device and a dynamically addressed network device of FIG. 1;

FIG. 4 is a block diagram illustrating an exemplary test setup message;

FIG. 5 is a block diagram of another exemplary network in which systems and methods described herein may be implemented;

FIG. 6 is another flow diagram illustrating exemplary processing associated with establishing a testing environment between a statically addressed network device and dynamically addressed network device; and

FIG. 7 is a flow diagram illustrating exemplary processing associated with establishing a testing environment between a first dynamically addressed network device and a second dynamically addressed network device.

### DETAILED DESCRIPTION OF PREFERRED EMBODIMENTS

The following detailed description refers to the accompanying drawings. The same reference numbers in different drawings may identify the same or similar elements. Also, the following detailed description does not limit the invention. Instead, the scope of the invention is defined by the appended claims and their equivalents.

Implementations described herein relate to testing of dynamically configured test points on a communications network. In one implementation, a first dynamically addressed test point may relay addressing information or other test setup information to second statically addressed test point. The second statically addressed test point may initiate testing using the received addressing information. In a second implementation, a network management system (NMS) may receive addressing information from one or both of the test points and may exchange the received addressing information with each respective test point to facilitate initiation of testing.

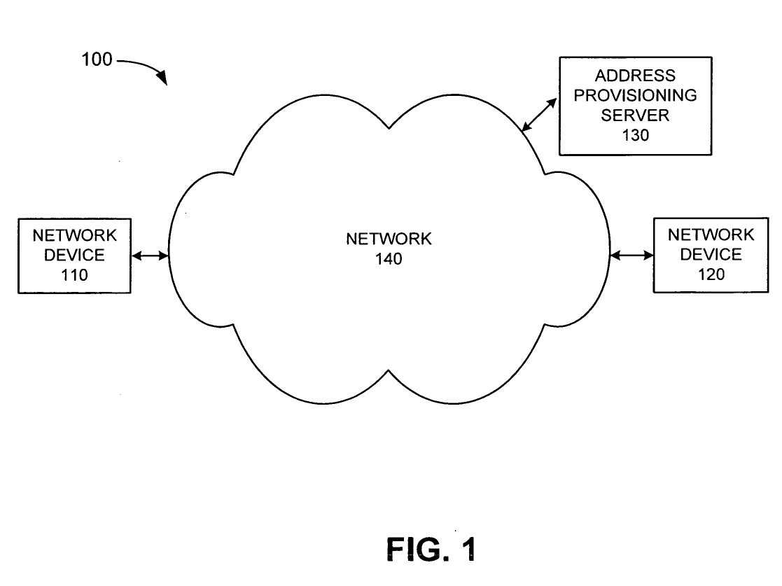

FIG. 1 is a block diagram of an exemplary network 100 in which systems and methods described herein may be implemented. Network 100 may include statically addressed network device 110, dynamically addressed network device 120, address provisioning server 130, and network 140. The number of elements illustrated in FIG. 1 is provided for simplicity. It should be understood that network 100 may include additional elements, such as additional network devices or provisioning servers.

Network devices 110 and 120 may represent any network equipment, such as customer premises equipment including time division multiplexed (TDM) circuits, telephone systems (e.g., a private branch exchange (PBX), a voice over Internet protocol (VoIP) system, etc.), one or more computers, one or more servers, one or more switches, one or more routers, associated with a customer, or other devices/systems associated with a customer. Additionally, network devices 110 and 120 may include other network equipment, such as one or more servers, network collection devices (NCDs), one or more devices for transmitting data to and receiving data from a network, such as network 140, via any number of protocols, such as Ethernet, Frame Relay, asynchronous transfer mode (ATM), time division multiplexing (TDM), Internet protocol (IP), etc.

Network devices 110 and 120 may include addressable layer 3 devices routable within network 100. Consistent with aspects described herein, one of network devices 110 and 120 (e.g., network device 110) may be a statically addressed network device that is provided with a static or nonchanging layer 3 network address, such as an Internet Protocol (IP) address. In some implementations, network device 110 may be provided with a static IP address by a service provider associated with network device 110. The other one of network devices 110 and 120 (e.g., network device 120) may be a dynamically addressed network device that is provided with an IP address by address provisioning server 130. The address provided by address provisioning server 130 may change over time based on the requirements of the network service provider associated with network 100 and the requirements of network device 120. For example, network device 120 may be a CPE router or access point that is configured to request an IP address lease from address provisioning server 130 (e.g., a dynamic host configuration protocol (DHCP) server) associated with network 100. In one implementation, network device 120 may request an IP address from address provisioning server 130 upon power-up or activation of a network adapter. The IP address assigned to network device 120 may be provided as a lease for a predetermined period of time.

Address provisioning server 130 may include any suitable network device configured to forward or assign network addresses to other network devices. As noted above, in one implementation address provisioning server may include a DHCP server associated with network 100. Address provisioning server 130 may receive network (e.g., IP) address requests from network devices, and may assign and provide network addresses in response thereto.

Network devices 110 and 120 may represent origination and destination devices associated with a dedicated private communication service between network device 110 and network device 120 that may be provided by a service provider associated with network 100. Network devices 110 and 120 may represent the same or different entities/customers that are provided with shared or dedicated communication services provided by a service provider associated with network 100.

In one implementation, network devices 110 and 120 may include one or more devices used to measure latency, packet loss, and/or jitter associated with data transmitted from network device 110 to network device 120, as described in detail below. In one implementation, network devices 110 and 120 may each represent a point of data aggregation. For example, network device 110 may be a building Ethernet aggregation system (BEAS) that aggregates Ethernet related customer traffic in a particular customer location (e.g., building, campus, etc.). In this implementation, network device 110 may forward the aggregated or collected customer traffic via network 140 using Ethernet, Gigabit Ethernet, etc. In some implementations, network devices 110 and 120 may also encapsulate the received data in accordance with the synchronous optical network (SONET) standard, via one or more plesiochronous circuits (e.g., DS1, DS3 circuits). Network devices 110 and 120 may also aggregate and forward data via other transport mechanisms/protocols, such as optical carrier level 3 (OC3), OC12, etc., based on the amount of data to be processed and the particular user requirements.

In still other implementations, network devices 110 and 120 may each represent a switch, a router, a gateway, etc., that receives data and routes the data via network 140 to a destination device. In each case, network devices 110 and 120 include measurement logic that is able to measure latency, packet loss, jitter, and/or other parameters associated with routing data via network 140. This measurement information may then be used to evaluate and determine network metrics relating to network service between devices 110 and 120 over network 140.

Network 140 may represent a network used to route traffic or data to/from various devices in network 100, such as network device 110 and network device 120. Network 140 may include a number of devices and links that may be used to connect network devices 110 and 120. Network devices 110 and 120 may connect to network 140 via wired, wireless, or optical communication mechanisms. For example, network devices 110 and 120 may connect to network 140 via a layer 2 network (e.g., an Ethernet network), point-to-point links, the public switched telephone network (PSTN), a wireless network, the Internet, or some other mechanism.

The exemplary configuration illustrated in FIG. 1 is provided for simplicity. It should be understood that a typical network may include more or fewer devices than illustrated in FIG. 1.

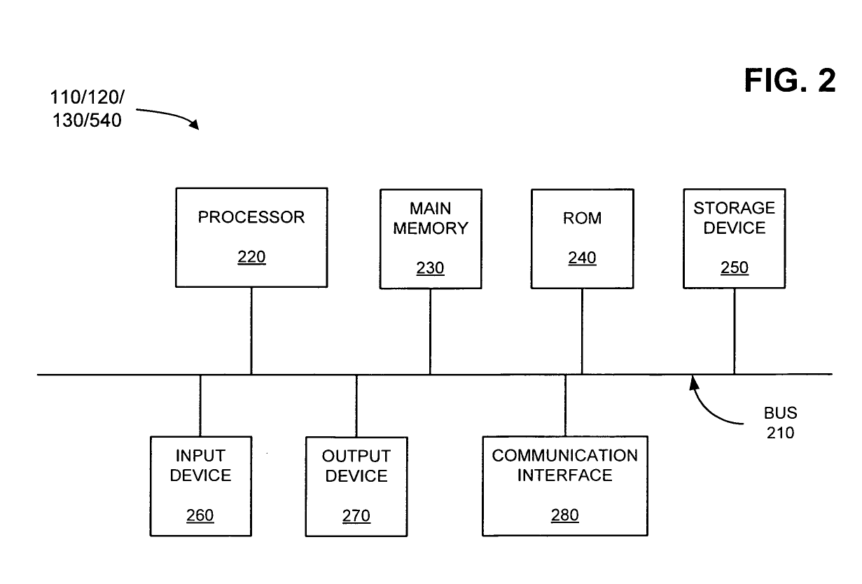

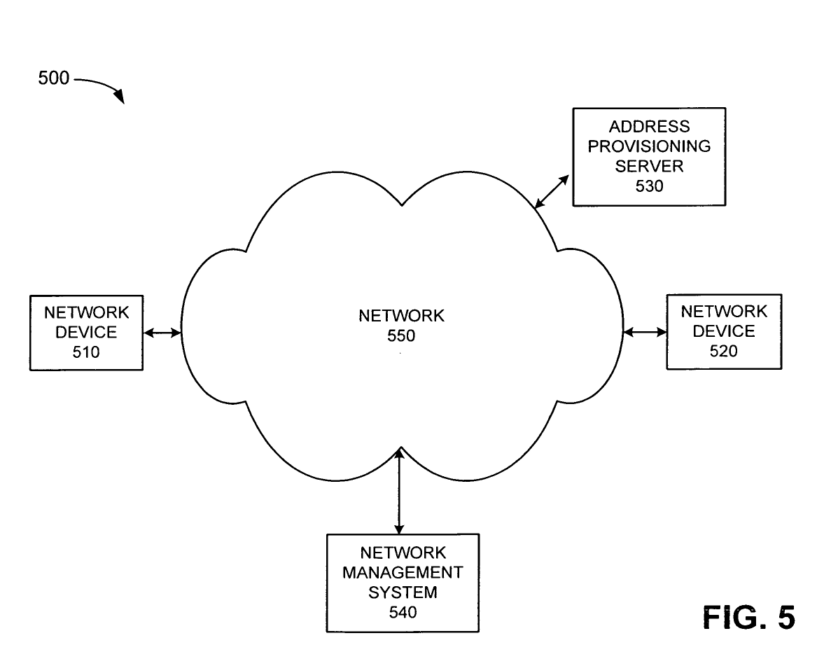

FIG. 2 is an exemplary diagram of a network device, which may correspond to one or more of network devices 110 and 120, address provisioning server 130, or network management system 540 discussed below in relation to FIG. 5. The network device may include a bus 210, a processor 220, a main memory 230, a read only memory (ROM) 240, a storage device 250, an input device 260, an output device 270, and a communication interface 280. Bus 210 may include a path that permits communication among the elements of the client/server entity.

Processor 220 may include a processor, microprocessor, or processing logic (e.g., an application-specific integrated circuit (ASIC), a field programmable gate array (FPGA), etc.) that may interpret and execute instructions. Main memory 230 may include a random access memory (RAM) or another type of dynamic storage device that may store information and instructions for execution by processor 220. ROM 240 may include a ROM device or another type of static storage device that may store static information and instructions for use by processor 220. Storage device 250 may include a magnetic and/or optical recording medium and its corresponding drive.

Input device 260 may include a mechanism that permits an operator to input information into the client/server entity, such as a keyboard, a mouse, a pen, voice recognition and/or biometric mechanisms, etc. Output device 270 may include a mechanism that outputs information to the operator, including a display, a printer, a speaker, etc. Communication interface 280 may include any transceiver-like mechanism that enables the client/server entity to communicate with other devices and/or systems. For example, communication interface 280 may include mechanisms for communicating with another device or system via a network, such as network 140.

As will be described in detail below, the network devices may perform certain network testing relating operations. The network devices entity may perform these operations in response to processor 220 executing software instructions contained in a computer-readable medium, such as memory 230. A computer-readable medium may be defined as a physical or logical memory device and/or carrier wave.

The software instructions may be read into memory 230 from another computer-readable medium, such as data storage device 250, or from another device via communication interface 280. The software instructions contained in memory 230 may cause processor 220 to perform processes that will be described later. Alternatively, hardwired circuitry may be used in place of or in combination with software instructions to implement processes described herein. Thus, implementations described herein are not limited to any specific combination of hardware circuitry and software.

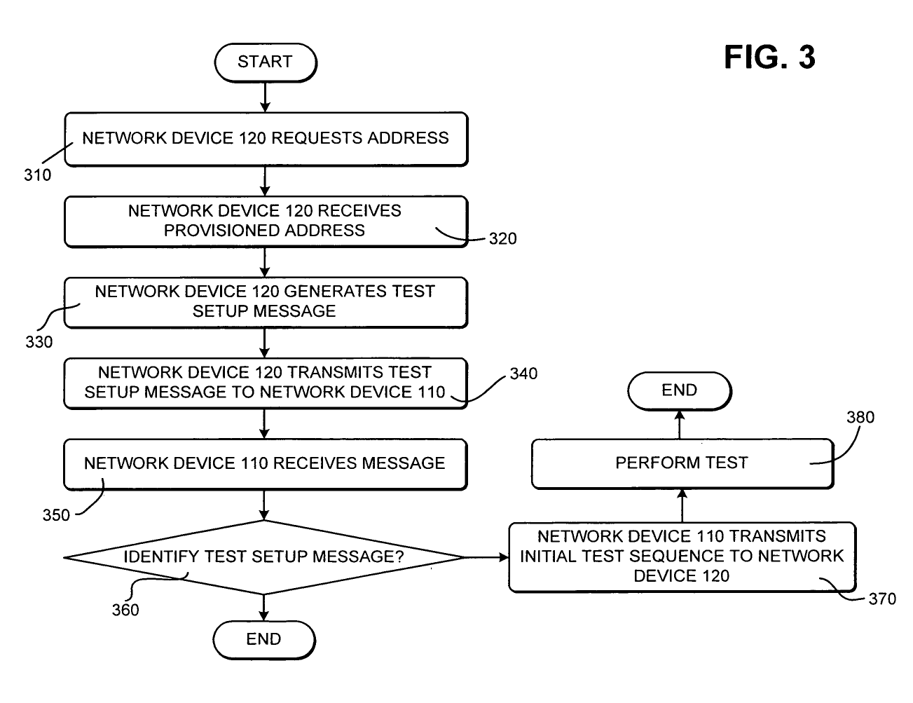

FIG. 3 is a flow diagram illustrating exemplary processing associated with establishing a testing environment between statically addressed network device 110 and dynamically addressed network device 120 in network 100. In this example, processing may begin with network device 120 requesting an address, e.g., an IP address, from address provisioning server 130 (block 310). Network device 120 may receive an IP address and lease details from address provisioning server 130 (block 320). Exemplary lease details include at least an expiration time and/or date associated with the assigned IP address.

Network device 120 may generate a test setup message (block 330). In one implementation, the test setup message may include several types of information including the IP address assigned to network device 120 by address provisioning server 130, lease duration or expiration information associated with the assigned address, and a network device identifier associated with network device 120. Consistent with aspects described herein, each network device associated with network 100 may be provided with a unique identifier used to identify each network device with respect to setting up device and network tests and maintaining test results associated with the tests.

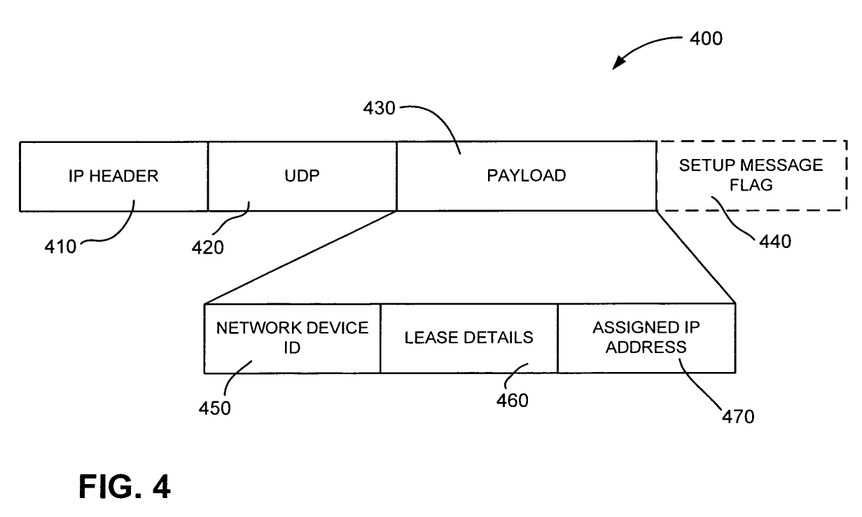

FIG. 4 is a block diagram illustrating an exemplary test setup message 400. As shown, test setup message may include an IP/UDP (user datagram protocol) packet that includes an IP header 410, a UDP field 420, a payload field 430, and a optional flag field 440. IP header field 410 may include IP routing information such as source and destination addresses, and packet protocol type. UDP field 420 may include source and destination ports for a UDP packet. Flag field 440 may optionally include a settable flag indicating that message 400 is a test setup message. Setting of flag field 440 to a predetermined value may enable a receiving network device (e.g., network device 110) to easily identify the received message as a test setup message.

As shown in the exploded illustration, payload field 430 may include several sub-fields including a network device identifier field 450, an IP address lease details field 460, and an assigned IP address field 470. As described above, each testable network device 110/120 may be provided with a unique identifier. This identifier may be provided in field 450. IP address lease details field 460 may include information regarding the duration or expiration of the lease associated with the assigned IP address. Assigned IP address field 470 may include the IP address assigned by address provisioning server 130.

It should be understood that, although test setup message 400 has been illustrated as an IPV4 packet, any suitable data unit may be used for transmitting test setup information between network device 120 and network device 110, such as IPV6, an ATM cell, a SONET overhead packet, etc. depending on the type of network and network devices under test.

Returning to FIG. 3, once test setup message 400 has been generated in block 330, it may be transmitted to network device 110 via network 140 (block 340). As described above, network device 110 may be provided with a static network (e.g., IP) address that is known to network device 120. Accordingly, the known IP address of network device 110 may be inserted into IP header field 410 of test setup message 400.

Network device 110 may receive message 400 (block 350) and may determine whether message 400 is a test setup message (block 360). In one embodiment, network device 110 may identify test setup message 400 in one of several manners. For example, test setup messages may be routed to a specific or known port or ports on network device 110. Alternatively, a value of flag field 440 may be retrieved and, if the value corresponds to a value associated with a test setup message, message 400 may be identified as a test setup message. In yet another implementation, network device 110 may base the determination on a type of packet received, where different types of packets may be used for different types of messages. It should be understood that the manner by which network device 110 recognizes a test setup message may be test protocol implementation dependent.

If the received message is not identified as a test setup message, the process may end (that is, the test related processing of network device 110 may end). However, if it is determined that the received message is a test setup message, network device 110 may send an initial test sequence to network device 120 via network 140 using the information received in the test setup message and based on preconfigured test profiles maintained on network devices 110 and 120 (block 370). Test profiles may include characteristics of the testing to be performed, such as test type, frequency, duration, packet size, etc. Testing may then continue between network devices 110 and 120 (block 380). The testing may include multiple test packets being transmitted between network device 110 and network device 120 using network device 110's statically assigned IP address and network device 120's dynamically assigned IP address.

FIG. 5 is a block diagram of another exemplary network 500 in which systems and methods described herein may be implemented. Network 500 may include a first network device 510, second network device 520, address provisioning server 530, network management system (NMS) 540, and network 550. The number of elements illustrated in FIG. 5 is provided for simplicity. It should be understood that network 500 may include additional elements, such as additional network devices or provisioning servers.

As in the embodiment of FIGS. 1-3, network devices 510 and 520 may represent any type of addressable network equipment, such as CPE equipment, servers, network collection devices (NCDs), one or more devices for transmitting data to and receiving data from a network, such as network 550, via any number of protocols, such as Ethernet, Frame Relay, asynchronous transfer mode (ATM), time division multiplexing (TDM), Internet protocol (IP), etc.

Network 550 may represent a network used to route traffic or data to/from various devices in network 500, such as network devices 510 and 520, address provisioning server 530, and network management system 540. Network 550 may include a number of devices and links that may be used to connect network devices 510 and 520, address provisioning server 530, and network management system 540. Network devices 510 and 520, address provisioning server 530, and network management system 540 may connect to network 550 via wired, wireless, or optical communication mechanisms. For example, network devices 510 and 520, address provisioning server 530, and network management system 540 may connect to network 550 via a layer 2 network (e.g., an Ethernet network), point-to-point links, the public switched telephone network (PSTN), a wireless network, the Internet, or some other mechanism.

The exemplary configuration illustrated in FIG. 5 is provided for simplicity. It should be understood that a typical network may include more or fewer devices than illustrated in FIG. 5. Network devices 510 and 520 may include addressable layer 3 devices routable within network 500. In one implementation, network device 510 may be a statically addressed network device that is provided with a static or nonchanging layer 3 network address, such as an IP address. In some implementations, network device 510 may be provided with a static IP address by a service provider associated with network device 510. In another implementation, each of network devices 510 and 520 may include dynamically addressed network devices that are provided with IP addresses by address provisioning server 530. The network addresses provided by address provisioning server 530 may change over time based on the requirements of the network service provider associated with network 500 and the requirements of network devices 510 and/or 520. For example, network devices 510 and/or 520 may be a CPE router or access point that is configured to request an IP address lease from address provisioning server 530 (e.g., a dynamic host configuration protocol (DHCP) server, or PPPoE (Point-to-Point Protocol over Ethernet architecture) associated with network 500. In one implementation, network devices 510 and/or 520 may request an IP address from address provisioning server 530 upon power-up or activation of a network adapter. The IP address assigned to network devices 510 and/or 520 may be provided as a lease for a predetermined period of time.

Network management system 540 may include a central testing system configured to facilitate testing between network device 510 and network device 520. Network management system 540 may be provided with a static network address known to both network device 510 and network device 520. Network management system 540 may facilitate testing by providing test setup information from dynamically addressed network devices (e.g., device 520) to statically addressed network devices 510. In one implementation, test profiles may be preconfigured on network devices 510 and 520. However, in an alternative implementation, network management system 540 may maintain the test profiles and forward the profiles to network devices 510 and 520 upon initiation of a test request or sequence.

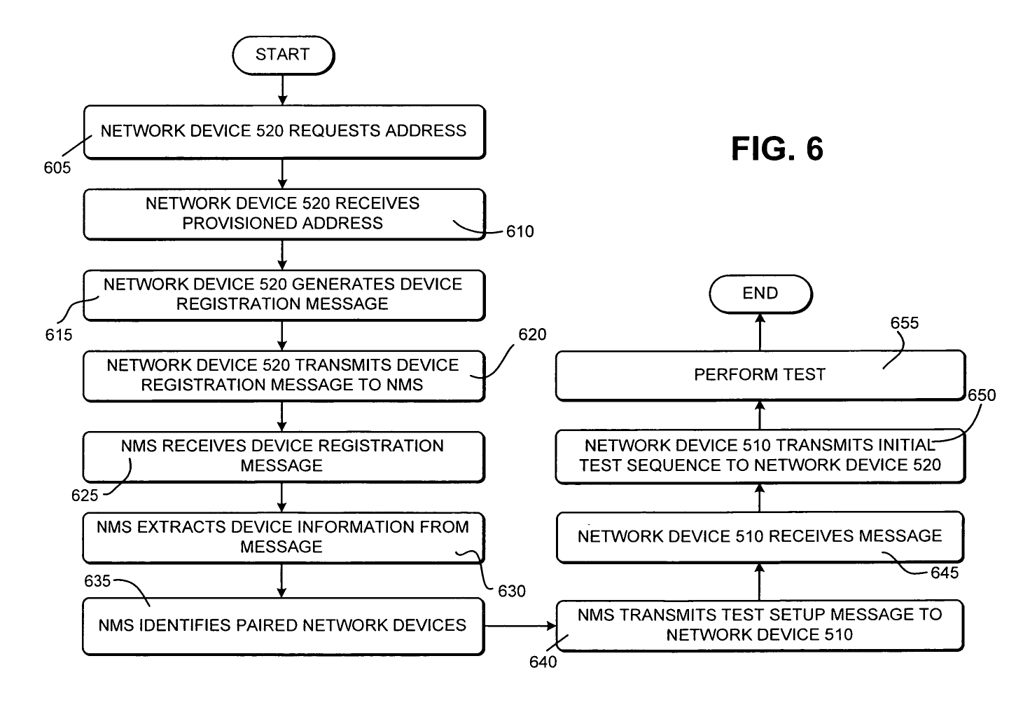

FIG. 6 is a flow diagram illustrating exemplary processing associated with establishing a testing environment between statically addressed network device 510 and dynamically addressed network device 520 in network 500. In this example, processing may begin with network device 520 requesting an address, e.g. an IP address from address provisioning server 530 (block 605). Network device 520 may receive an IP address and lease details from address provisioning server 530 (block 610). Exemplary lease details include at least an expiration time and/or date associated with the assigned IP address.

Network device 520 may generate a device registration message, similar to test setup message 400 that includes the IP address and lease details assigned by address provisioning server 530 as well as the unique network device identifier associated with network device 520 (block 615). Next, the device registration message may be transmitted to network management system 540 via network 550 (block 620). As described above, network management system 540 may have a network address that is known to network device 520. This known IP address of network management system 540 may be inserted into IP header field 410 of the device registration message.

Network management system 540 may receive the device registration message (block 625) and extract network device 520's identifier, IP address, and lease conditions from the received message (block 630). Network management system 540 may identify network device 510 as being associated or paired with the received registration message, by for example, looking up test groupings in a database or lookup table (block 635). Network management system 540 may transmit a test setup message to network device 510 that includes the network device identifier, IP address, and lease details associated with network device 520 (block 640).

Upon receipt of the test setup message from network management system 540 (block 645), network device 510 may send an initial test sequence to network device 520 via network 550 using the information received in the second test setup message and based on preconfigured test profiles maintained on network devices 510 and 520 (block 650). Test profiles may include characteristics of the testing to be performed, such as test type, frequency, duration, packet size, etc. Testing may then continue between network devices 510 and 520 (block 655). The processing of FIG. 6 may be considered out-of-band processing, wherein network devices 510 and 520 do not need any a priori knowledge of each other and wherein test setup may be performed using an out-of-band management channel.

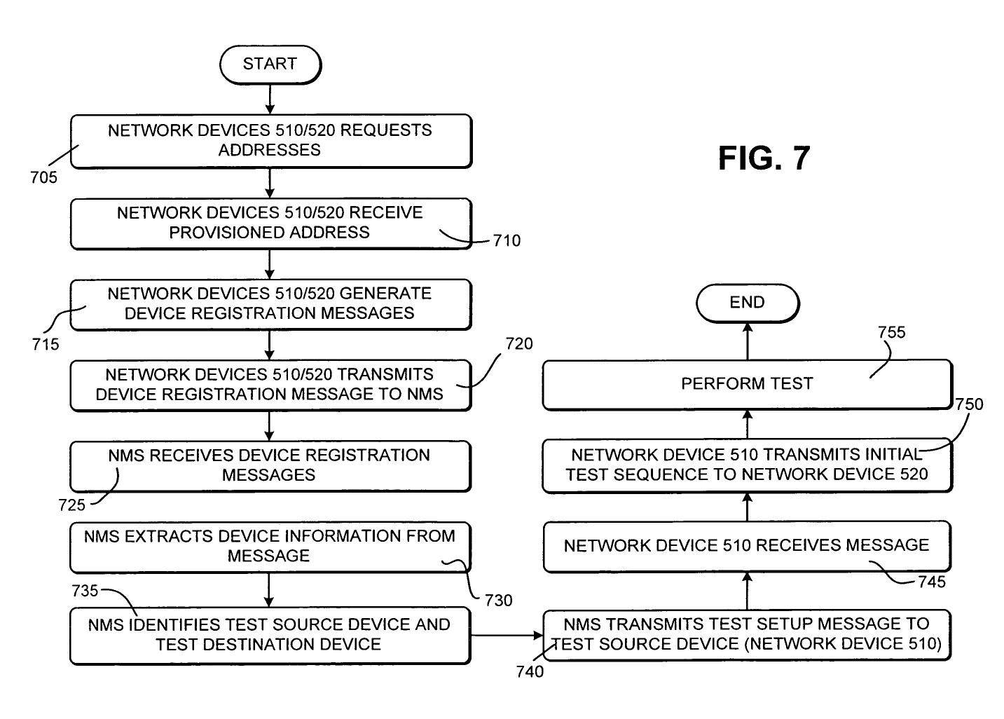

FIG. 7 is a flow diagram illustrating exemplary processing associated with establishing a testing environment between a first dynamically addressed network device 510 and second dynamically addressed network device 520 in network 500. In this example, processing may begin with network devices 510 and 520 each requesting addresses, e.g., IP addresses from address provisioning server 530 (block 705). In alternative implementations, network devices 510 and 520 may be associated with different address provisioning servers. Network devices 510 and 520 may each receive an IP address and lease details from address provisioning server 530 (block 710). Exemplary lease details for each of network devices 510 and 520 may include at least an expiration time and/or date associated with the assigned IP address.

Network devices 510 and 520 may each generate device registration messages, similar to test setup message 400, that include their respective device identifiers, IP addresses, and lease details assigned by address provisioning server 530 (block 715). Next, the device registration messages may be transmitted to network management system 540 via network 550 (block 720). As described above, network management system 540 may have a network address that is known to network devices 510 and 520. This known IP address of network management system 540 may be inserted into IP header field 410 of the device registration messages transmitted by each of network device 510 and 520.

Network management system 540 may receive the device registration messages (block 725) and may extract the network device identifiers, IP addresses, and lease conditions from each received message (block 730). Network management system 540 may then identify respective test source network devices and test destination network devices associated with each received registration message, by for example, looking up test pairings or groupings in a database or lookup table (block 735). In one implementation, each testing operation initiates with a test source device transmitting an initial test sequence to a test destination device. By identifying test source devices associated with the received test setup messages, network device identifiers and addressing information may be provided to an appropriate test source device. In the embodiment of FIG. 7, network device 510 may be the test source network device and network device 520 may be the test destination device.

Once network management system 540 identifies network device 510 as the test source network device, a test setup message may be transmitted to network device 510 that includes the network device identifier, IP address, and lease details associated with network device 520 (block 740). Upon receipt of the second test setup message from network management system 540 (bock 745), network device 510 may send an initial test sequence to network device 520 via network 550 using the information received in the test setup message and based on preconfigured test profiles maintained on network devices 510 and 520 (block 750). Test profiles may include characteristics of the testing to be performed, such as test type, frequency, duration, packet size, etc. Test types may include packet loss testing, jitter testing, throughput testing, packet latency testing, etc. Testing may then continue between network devices 510 and 520 (block 755). The processing of FIG. 7 may be considered out-of-band processing between multiple dynamically addressed network devices, wherein network devices 510 and 520 do not need any a priori knowledge of each other and wherein registration and test setup messages maybe exchanged using out-of-band management channels.

As described above, the system of FIG. 5 may be configured as a network management system centered testing system, where the testing profile information may be maintained and distributed by network management system 540 and need not be preconfigured on either of network devices 510 or 520. In this implementation, network management system 540 may maintain a test table identifying test profiles and characteristics associated with each network device associated with network management system 540. For example, the test table may include test profile identifiers, test source network device identifiers, and test destination network identifiers. Upon receipt of the registration messages from network devices 510 and 520, network management system 540 may identify test profiles associated with the devices and may forward the configuration commands in the test setup message to the identified source network device.

Implementations described herein provide for facilitating of active network testing between statically and dynamically addressed network devices. The foregoing description of exemplary implementations provides illustration and description, but is not intended to be exhaustive or to limit the invention to the precise form disclosed. Modifications and variations are possible in light of the above teachings or may be acquired from practice of the invention.

In addition, while series of block have been described with respect to FIGS. 3, 6, and 7, the order of the blocks may be varied in other implementations. Moreover, non-dependent acts may be implemented in parallel.

It will be apparent to one of ordinary skill in the art that various features described above may be implemented in many different forms of software, firmware, and hardware in the implementations illustrated in the figures. The actual software code or specialized control hardware used to implement the various features is not limiting of the invention. Thus, the operation and behavior of the features of the invention were described without reference to the specific software code—it being understood that one of ordinary skill in the art would be able to design software and control hardware to implement the various features based on the description herein.

Further, certain portions of the invention may be implemented as “logic” that performs one or more functions. This logic may include hardware, such as a processor, a microprocessor, an application specific integrated circuit, or a field programmable gate array, software, or a combination of hardware and software.

No element, act, or instruction used in the description of the present application should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A method, comprising:
receiving, at a first network device, a message from a second network device;
determining whether the message is a test setup message, where the test setup message includes a network address associated with the second network device; and
initiating a test sequence with the second network device based on the network address when it is determined that the message is a test setup message.

2. The method of claim 1, wherein the second network device is a dynamically addressable network device.

3. The method of claim 2, wherein the second network device obtains the network address from an address provisioning server.

4. The method of claim 1, wherein the test setup message comprises a packet, where the packet includes a payload portion that includes at least an identifier associated with the second network device and the network address associated with the second network device.

5. The method of claim 4, where the payload portion of the test setup message includes an address lease time associated with the network address.

6. The method of claim 1, where determining whether the message is a test setup message further comprises:
determining whether the message was received on a port associated with test setup messages.

7. The method of claim 1, where the determining whether the message is a test setup message further comprises:
determining whether a flag field associated with the received message includes a value indicative of a test setup message.

8. The method of claim 1, where the first network device and the second network device are preconfigured to include test profile information regarding the initiated test sequence.

9. A system, comprising:
a first network device having a statically assigned network address;
a second network device operatively connected to the first network device via a network; and
an address provisioning server operatively connected to the second network device via the network,
where the second network device is configured to:
receive a network address from the address provisioning server;
generate a test setup message including the network address; and
transmit the test setup message to the first network device using the statically assigned network address.

10. The system of claim 9, where the first network device is configured to:
receive the test setup message from the second network device; and
transmit an initial test sequence to the second network device using the network address included in the test setup message.

11. The system of claim 10, where the first network device is further configured to:
receive a message from the second network device;
determine whether the received message is the test setup message; and
transmit the initial test sequence to the second network device using the network address included in the test setup message when it is determined that the received message is the test setup message.

12. A network management system, comprising:
logic to receive a first registration message from a first network device, where the registration message includes at least a first network device identifier and a first network address associated with the first network device;
logic to identify a test grouping including the first network device based on the first network device identifier; and
logic to transmit a test setup message to a second network device identified in the test grouping, where the test setup message includes at least the first network address.

13. The network management system of claim 12, where the registration message includes lease details relating to the network address.

14. The network management system of claim 12, where the logic to identify a test grouping including the first network device further includes:
logic to extract the first network device identifier from the registration message;
logic to identify a second network identifier associated with the second network device based on the first network device identifier; and
logic to identify a second network address associated with the second network device based on the second network identifier.

15. The network management system of claim 14, where the second network address comprises a statically assigned address and the first network address comprises a dynamically assigned address.

16. The network management system of claim 12, further comprising:
logic to receive a second registration message from the second network device, where the second registration message includes at least the second network device identifier and the second network address associated with the second network device, the second network address being a dynamically assigned address;
logic to identify the test grouping including the first network device and the second network device based on the first network device identifier and the second network device identifier; and
logic to identify the second network device as a test source device in the test group.

17. A system, comprising:
means for receiving a dynamically assigned network address;
means for generating a test setup message including the dynamically assigned network address receiving and a network device identifier;
means for forwarding the test setup message to a test source network device via a network;
means for receiving a test sequence from the test source network device; and
means for performing active testing with the test source network device.

18. The system of claim 17, where the test setup message includes lease details associated with the dynamically assigned network address.

19. A method, comprising:
receiving a first registration message from a first dynamically addressable network device, where the first registration message includes at least a first network identifier and a first network address associated with the first dynamically addressable network device;
receiving a second registration message from a second dynamically addressable network device, where the second registration message includes at least a second network identifier and a second network address associated with the second dynamically addressable network device;
identifying a test grouping including the first dynamically addressable network device and the second dynamically addressable network device based on the first registration message and the second registration message, where the first dynamically addressable network device is designated as a test source device and the second dynamically addressable network device is designated as the test destination device;
transmitting a test setup message to the first dynamically addressable network device, wherein the test setup message includes at least the second network identifier and the second network address associated with the second dynamically addressable network device; and
transmitting test configuration settings to the to the first dynamically addressable network device, where the test configuration settings include at least one of: a type of test, a duration of the test, a frequency of the test, or a number of packets to transmit during the test.

20. The method of claim 19, where the test configuration settings include at least one of: test type, test duration, test frequency, or test packet size.
